(19) United States
(12) Patent Application Publication
(10) Pub. No.: US 2002/0081380 A1
(43) Pub. Date: Jun. 27, 2002

(54) Highly purified single-wall carbon nanotubes and production thereof

(76) Inventors: Anne C. Dillon, Boulder, CO (US); Thomas Gennett, Pittsford, NY (US); Michael J. Heben, Denver, CO (US)

Correspondence Address: PAUL J WHITE, SENIOR COUNSEL, NATIONAL RENEWABLE ENERGY LABORATORY (NREL), 1617 COLE BOULEVARD, GOLDEN, CO, 80401-3393, US

(21) Appl. No.: 10/076,195

(22) Filed: Feb. 12, 2002

Related U.S. Application Data
(63) Continuation-in-part of application No. PCT/US00/22034, filed on Aug. 11, 2000.
(60) Provisional application No. 60/148,483, filed on Aug. 12, 1999.

(51) Int. Cl. C23C 16/26

(52) U.S. Cl. 427/249.1

(57) ABSTRACT

Highly purified single-wall carbon nanotubes (SWNTs) and production thereof. The highly purified single-wall carbon nanotubes may be produced according to one embodiment of the invention by generating a crude SWNT material having a carbon nanotube fraction and a non-nanotube carbon fraction, refluxing the crude SWNT material in an acid solution to redistribute the non-nanotube carbon fraction as a uniform carbon coating on the carbon nanotube fraction, and oxidizing the refluxed SWNT material to remove the uniform carbon coating formed thereon. Preferably, metal is also removed during reflux.

### RELATED APPLICATIONS AND INCORPORATION BY REFERENCE

This is a continuation-in-part application based on International Application No. PCT/US00/22034 titled “PURE SINGLE-WALL CARBON NANOTUBES” of A. C. Dillon, et al. and filed on Aug. 11, 2000, which claims priority to U.S. Provisional Patent Application No. 60/148,483 filed on Aug. 12, 1999. The international application was published under PCT Article 21(2) in English on Feb. 22, 2001. Each application is hereby incorporated by reference for all that is disclosed therein.

### CONTRACTUAL ORIGIN OF THE INVENTION

The United States Government has rights in this invention pursuant to Contract No. DE-AC36-99GO10337 between the United States Department of Energy and the Midwest Research Institute.

### TECHNICAL FIELD

This invention relates to single-wall carbon nanotubes (SWNTs) and, in particular, to highly purified single-wall carbon nanotubes and the production thereof.

### BACKGROUND ART

Single-wall carbon nanotubes (SWNTs) are well-known in the art and generally comprise single layer tubes or cylinders in which a single layer of carbon is arranged in the form of a linear fullerene. The single layer tubes or cylinders comprising SWNTs generally have diameters in the range of about 1-2 nanometers (nm) and lengths on the order of microns, thus making SWNTs “high aspect ratio” particles. SWNTs have a variety of unique electronic, optical, and mechanical properties that make them promising candidates for a wide range of applications, including, gas storage and separation, fuel cell membranes, batteries, photovoltaic devices, composite materials, and nanoscale wires and interconnects, just to name a few. However, in addition to the SWNT structures, crude SWNTs typically also include impurities, such as metals and non-nanotube carbon fractions. Therefore, before any of the advantages and applications of SWNTs can be effectively realized, a process must be developed for producing high purity SWNT structures using methods that can be readily scaled for the large-scale production thereof.

While several different methods for purifying SWNTs have been developed and are being used, none have provided an acceptable balance of high purity and low cost while producing substantial quantities of highly purified SWNT product. For example, one process for purifying SWNTs is disclosed by A. G. Rinzler, et al., in Applied Physics A 1998, 67, 29, which requires more than twenty-one steps and several days of processing to produce a SWNT product that is only 90 wt % pure. Other processes, such as that disclosed by S. Bandow, et al., in J. Phys. Chem. B 1997, 101, 8839, are not suitable for large-scale production. Still other processes may damage the SWNT structures.

Consequently, a need remains for a non-destructive process for producing highly purified SWNTs. Additional advantages would be realized if such a process were readily scalable, thereby allowing for the large scale, economical production of a highly purified SWNT product.

### DISCLOSURE OF INVENTION

A highly purified single-wall carbon nanotube (SWNT) produced according to embodiments of the method of the invention.

An embodiment of a method for producing a highly purified single-wall carbon nanotube (SWNT) product may comprise the steps of: refluxing crude SWNT material in a solution to produce a refluxed SWNT material having at least a partial carbon coating thereon, and oxidizing the refluxed SWNT material to remove at least a portion of the carbon coating formed thereon.

Another embodiment of a method for producing highly purified single-wall carbon nanotubes (SWNTs) may comprise the steps of: generating crude SWNT material having a carbon nanotube fraction and a non-nanotube carbon fraction, refluxing the crude SWNT material in an acid solution to redistribute the non-nanotube carbon fraction as a uniform carbon coating on the carbon nanotube fraction, and oxidizing the refluxed SWNT material to remove the uniform carbon coating formed thereon.

### BRIEF DESCRIPTION OF THE DRAWINGS

Illustrative and presently preferred embodiments of the invention are shown in the accompanying drawings in which:

FIG. 1 is a transmission electron microscopy (TEM) image of crude single-wall carbon nanotube (SWNT) material produced according to an embodiment of the invention;

FIG. 2 is a TEM image of refluxed SWNT material produced according to an embodiment of the invention;

FIG. 3 is a TEM image of highly purified SWNT material following oxidation according to an embodiment of the invention;

FIG. 4 is a TEM image of highly purified SWNT material following high-temperature annealing according to an embodiment of the invention;

FIG. 5 shows thermal gravimetric analysis (TGA) data for crude SWNT material, refluxed SWNT material, and highly purified SWNT product produced according to an embodiment of the invention;

FIG. 6 shows TGA data for SWNT material refluxed for 4 hours, 16 hours, and 48 hours; and

FIG. 7 shows Raman spectra for crude SWNT material, refluxed SWNT material, and highly purified SWNT product produced according to an embodiment of the invention.

### BEST MODES FOR CARRYING OUT THE INVENTION

A highly purified single-wall carbon nanotube (SWNT) product and the production thereof is shown and described herein according to preferred embodiments of the invention. Briefly, SWNTs have been studied for a variety of different uses. However, the benefits of using SWNTs for such applications are generally best realized when a highly purified SWNT material is used. Although other processes have been disclosed for purifying raw or crude SWNT material, such processes typically result in the production of a SWNT product that is only about 90 wt % pure, and are not suitable for large-scale production. In fact, in some of the other processes, some of the SWNT product may even be damaged or destroyed during the purification process.

According to embodiments of the invention, a highly purified single-wall carbon nanotube (SWNT) product may be produced in a non-destructive manner. One such embodiment for purifying SWNTs may comprise refluxing a crude SWNT material in a solution to produce a refluxed SWNT material having at least a partial carbon coating formed thereon. The refluxed SWNT material may be oxidized (e.g., in air) to remove at least a portion of the carbon coating formed thereon. Preferably, most, if not all of the metal is also removed to produce a highly purified SWNT product.

Another embodiment of a process for producing a highly purified SWNT product may comprise generating a crude SWNT material having at least a carbon nanotube fraction and a non-nanotube carbon fraction. The crude SWNT material is preferably refluxed in an acid solution (e.g., dilute nitric acid) to redistribute the non-nanotube carbon fraction as a uniform carbon coating on the carbon nanotube fraction, which may then be removed by oxidizing the refluxed SWNT material. Again, preferably most, if not all of the metals are also removed during the purification process.

A significant advantage of the methods for purifying SWNTs according to embodiments of the invention is the relatively high purity of the SWNT product. In one embodiment, the SWNT product is at least 98 wt % pure and has a metal content of less than 0.5 wt %. In addition, the purification process is non-destructive, and is readily scalable.

Having briefly described highly purified SWNTs and embodiments of the production thereof, as well as some of the more significant advantages associated therewith, the various embodiments of the present invention will now be described in greater detail below. The highly purified SWNT product may be produced according to the teachings of the invention from raw or crude SWNTs (i.e., having at least some impurities) synthesized according to any suitable technique. Preferably, the crude SWNT material is synthesized from a pressed-powder graphite target using a laser vaporization method, such as that reported by A. Thess, et al., in Science 1996, 273, and discussed in more detail below with respect to specific examples of the invention. Also preferably, the laser is maintained in a vaporization regime during synthesis to reduce the formation of graphite particles and graphite-encapsulated metal particles, which may be difficult to remove by refluxing and oxidation according to embodiments of the invention. However, other synthesis processes may also be used for producing the crude SWNT material, such as but not limited to, chemical vapor deposition and arc discharge methods, and are also contemplated as being within the scope of the invention.

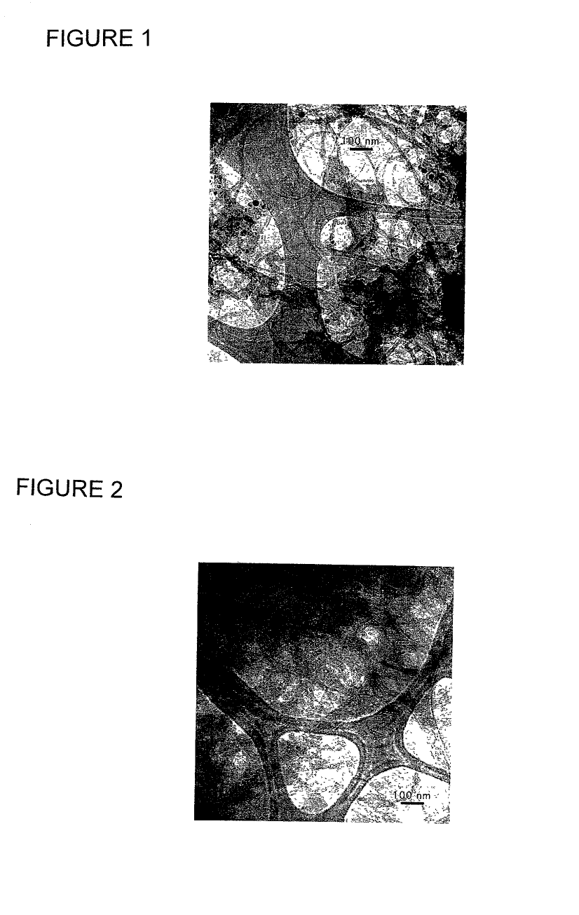

The crude SWNT material may be viewed in accordance with any of a number of microscopy techniques. Images produced by a transmission electron microscope in a process generally referred to as transmission electron microscopy (TEM), are shown in FIG. 1 of the crude SWNT material produced according to one embodiment of the invention. As is readily apparent, bundles of SWNT structures span between large agglomerations of amorphous and micro-crystalline carbon and metal nanoparticles.

Typical crude SWNT material was estimated to contain about 20 to 30 wt % of the SWNT structures by a detailed analysis of numerous different TEM images. See A. C. Dillon, et al., Mater. Res. Soc. Conf. Proc. 1998, 526, 403. A more precise determination of the wt % may be determined using thermal gravimetric analysis (TGA), for example, as reported by A. C. Dillon, et al., Adv. Mat. 11 (1999) 1354. Further analysis of the crude SWNT material by inductively coupled plasma spectroscopy (ICPS) indicated that the laser-generated crude SWNT material has the same metal content as the pressed-graphite target material (i.e., about 6 wt %). However, previous studies have shown that the laser-generated crude SWNT material may contain more metal than the target material. See E. Dujardin, et al., Adv. Materials 1998, 10, 611.

The crude SWNT material is preferably refluxed in solution. According to one embodiment, the solution may comprise dilute nitric acid solution (e.g., 3 molar (M) HNO₃). During the reflux process, the non-nanotube carbon fractions may be redistributed as a thin, uniform coating on the SWNT structures, as shown by the TEM image in FIG. 2. In addition, the reflux process removes at least a portion, and preferably most, if not all, of the metal incorporated with the crude SWNT material, such as metals from the graphite target material and/or those otherwise introduced during synthesis of the crude SWNT material. Of course it is understood that any suitable acid at any suitable concentration may be used to remove the metal and functionalize the carbon impurities.

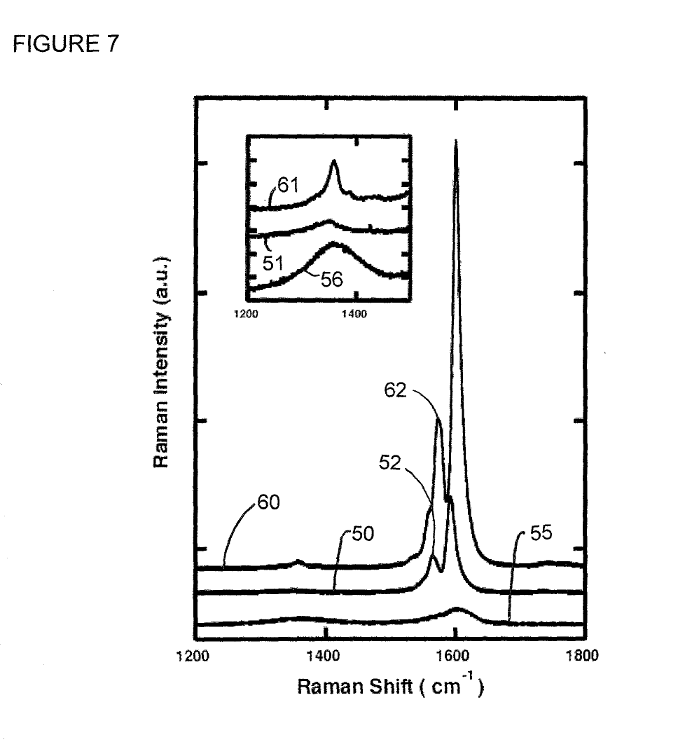

The reflux may also introduce reactive functional groups onto the surfaces of the nonnanotube carbon material, as indicated by temperature programmed desorption (TPD) analysis. In addition, the reflux may decrease the domain size of the disordered carbon (as shown in the Raman spectra of FIG. 7, discussed in more detail below), and preferably reorganizes the non-nanotube carbon fraction as a high surface area, uniform carbon coating on the SWNT structures.

Furthermore, as the functionalized carbon coating is generally evenly distributed on the SWNT structures and is oxidized at lower temperatures than the SWNT structures, the heat generated during exothermic reactions does not damage or consume the SWNT structures.

A combination of the high-surface area, decreased domain size, functional groups formed on the carbon coating, uniformity of the carbon coating, and removal of metal particles during the reflux allows non-destructive purification of SWNT structures by oxidation (i.e., minimal or no destruction of the SWNT structures). Thus, following reflux of the crude SWNT material, the refluxed SWNT material is preferably separated from solution, as shown in the TEM image of FIG. 2, so that the refluxed SWNT material may be oxidized according to a preferred embodiment the invention.

The refluxed SWNT material may be collected on a filter that allows the ready separation of the nanotubes from the solution. By way of example, the refluxed SWNT material may be collected with an 0.2 micrometer (μm) polypropylene filter coated with polytetrafluoro ethylene (PTFE), and rinsed (e.g., using deionized water). Of course, it is understood that any suitable filter 30 brand, type, and/or size may be used according to the teachings of the invention. For example, larger filters may be used to scale the process. Or for example, an alumina filter may be used. Or for example, burnable filters (e.g., ashless filter paper) may be used, wherein the filter material burns off (e.g., at less than 550° C.) and separates from the SWNT material collected thereon during oxidation of the refluxed SWNT material.

It is also understood that any suitable process for separating the refluxed SWNT material from the solution may be used according to the teachings of the present invention. For example, the refluxed SWNT material may first be collected on several smaller filters, which are then added to another solution (e.g., toluene). The suspended SWNT material may then be evaporated from the second solution and collected as a thin film. Evaporation of the solution may be enhanced, for example, using a Rotovap, or the like. Accordingly, the refluxed SWNT material from multiple filters may be collected, and the process may be readily scaled.

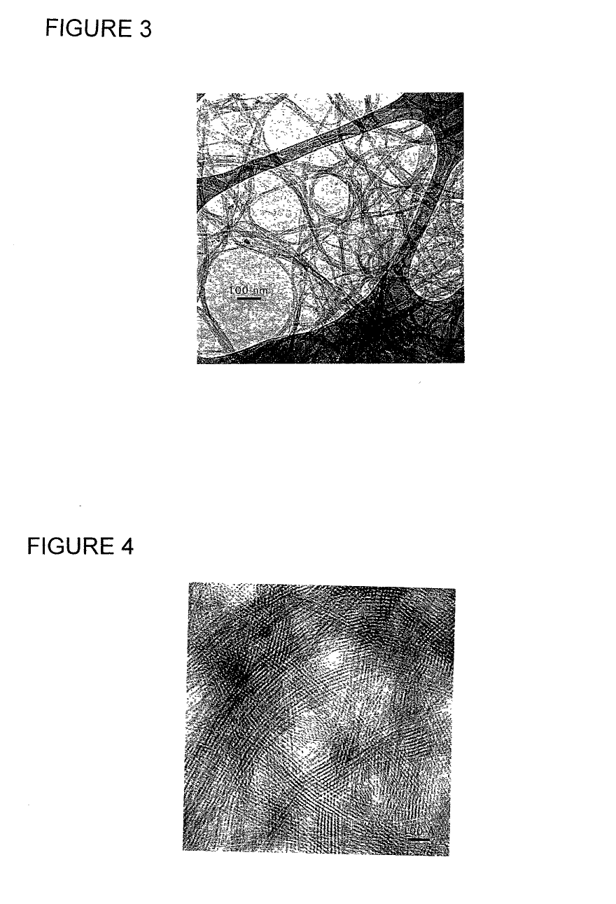

According to preferred embodiments of the invention, the refluxed SWNT material may be oxidized. Oxidation removes at least a portion of, and preferably most, if not all, of the non-nanotube carbon fraction that was redistributed as a uniform coating on the SWNT structures during the reflux procedure. The refluxed SWNT material may be oxidized according to any suitable process. Preferably, the refluxed SWNT material is oxidized using stagnant air while heating it inside a tube furnace until the desired portion of the carbon coating is removed from the SWNT structures. For example, the refluxed SWNT material may be oxidized in stagnant air inside a tube furnace heated to about 550° C. for about 30 minutes. Accordingly, the carbon coating may be completely removed, thereby producing highly purified SWNT material, as shown in the TEM image of FIG. 3. However, it is understood that any gas-phase oxidant may be used, such as oxygen gas, carbon dioxide gas, etc.

The highly purified SWNT material is also shown in the TEM image of FIG. 4, following an optional, high-temperature annealing process. According to one embodiment of the invention, the highly purified SWNT product is heated to about 1500° C. in a vacuum to remove the metal that was not previously removed during the reflux procedure (e.g., the graphite encapsulated metal introduced during synthesis). High-temperature annealing causes reordering in the SWNT bundles and permits high resolution TEM imaging.

The SWNT material may be characterized at various stages of the method of the invention according to any of a variety of analytical techniques that are now known or that may be later developed. For example, the SWNT material may be analyzed using thermal gravimetric analysis (TGA). TGA is a process wherein changes in the weight of a sample are recorded as a function of temperature during exposure of the sample to a stepped temperature program, typically ranging from room temperature to about 1000° C. The recorded data is indicative of temperature-dependent characteristics of the sample, for example, and may be used to determine the composition of the sample by weight.

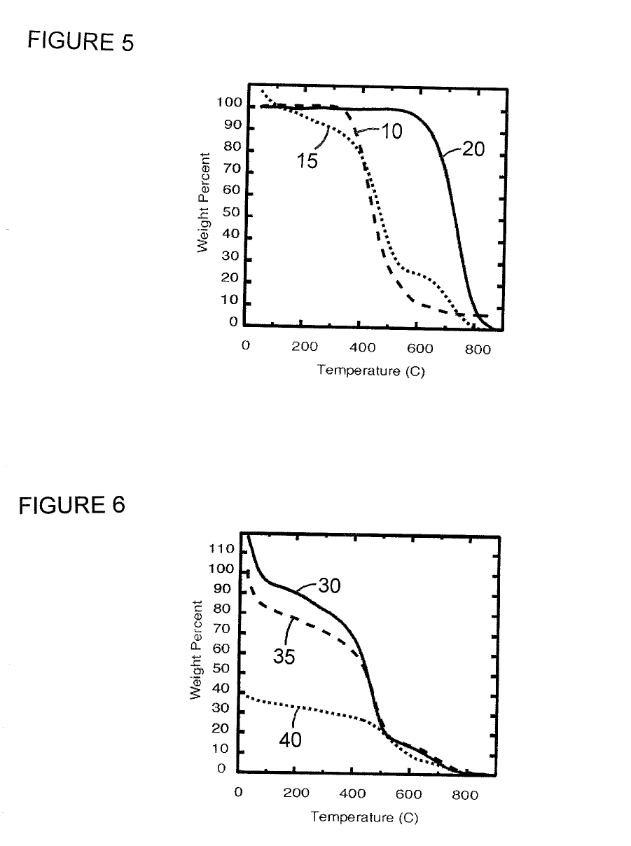

The TGA data for the crude SWNT material is shown by the dashed-line 10 in FIG. 5. An initial increase in the sample weight may be observed due to the added weight of the oxygen as the metal (e.g., nickel (Ni) and cobalt (Co)) oxidizes (e.g., forming cobalt-oxide and nickel-oxide). As the sample is heated between about 370° C. and 600° C., the decrease in sample weight may be attributed to the combustion of the carbonaceous fraction of the sample (i.e., both the SWNT structures and the non-nanotube carbon fraction). The oxidation of agglomerated impurities, especially metal catalyst materials, generate “hot spots” that enhance the oxidation kinetics of the SWNT structures. Therefore, both the non-nanotube carbon fraction and the SWNT structures may be consumed simultaneously. A small final weight loss at about 650° C. may be attributed to the oxidation of any remaining SWNT structures (about 5 wt %). The remaining weight (about 8 wt %) at 875° C. corresponds to the weight of the oxidized metals.

Several properties of the refluxed SWNT material are readily apparent from the TGA data shown by the dotted-line 15 in FIG. 5. The initial decline in sample weight (up to about 100° C.) may be attributed to the evaporation of water from the sample, indicating that the refluxed SWNT material is hygroscopic. Indeed, the refluxed SWNT material may take on as much as 10 wt % water from the ambient air. Accordingly, the results indicate that carboxyl, aldehyde, and other oxygen-containing functional groups may form on the surface of the non-nanotube carbonaceous fractions during the reflux procedure. These functional groups may make the carbon film formed on the refluxed SWNT material more reactive and thus may aid in oxidation of thereof.

Unlike the TGA data 10 for the crude SWNT material, which exhibited an initial increase in sample weight attributable to the oxidation of metals in the sample, the TGA data 15 for the refluxed SWNT material does not exhibit this initial increase in sample weight. In addition, the refluxed SWNT sample weight is reduced to approximately zero by 850° C. Accordingly, the TGA data for the refluxed SWNT material indicates that most, if not all, of the metal that is initially present in the crude SWNT material is removed during the reflux process.

Also unlike the TGA data 10 for the crude SWNT material, in which decomposition of the non-nanotube carbon fraction and the SWNT structures is indistinguishable, the TGA data 15 for the refluxed SWNT material indicates that the non-nanotube carbon fraction begins to combust at a lower temperature (about 350° C. to 400° C.) and is completed before onset of the combustion of the SWNT structures (about 650° C.). The separate combustion of each component is accentuated by the plateau in the TGA curve 15 that is present between about 550° C. to 650° C. The TGA data 15 thus indicates that the non-nanotube carbon fraction is arranged as a carbon coating on the SWNT structures during reflux, and is readily oxidized at lower temperatures than the SWNT nanotube structures. Accordingly, oxidation at temperatures less than about 650° C., and preferably at about 550° C., may effectively remove the non-nanotube fraction without damaging the SWNT structures. When the refluxed SWNT material is heated above about 550° C., the sample comprises mostly highly purified SWNTs which may be quantified as about 26 wt % of the dry refluxed material, or about 21 wt % of the pre-reflux weight, indicating the quantity of tubes in the as produced sample.

To determine whether the SWNT structures are damaged and/or consumed during the reflux procedure, the crude SWNT material may be refluxed for varying durations and analyzed by TGA. As an illustration, the TGA data is shown in FIG. 6 for the crude SWNT material following reflux at 4 hours (solid line 30) and at 16 hours (dashed line 35) in 3 M HNO₃. The TGA data shown in FIG. 6 is adjusted for the dry-weight lost during reflux so that the y-axis represents the wt % remaining of the initial crude SWNT material. The data for both the 4 hour reflux (solid line 30) and the 16 hour reflux (dashed line 35) are substantially coincident at temperatures above about 450° C. In addition, a plateau in the TGA data is observed at 540° C. and a SWNT content of 17 wt %. As discussed earlier, the SWNT structures are not consumed by oxidation below 550° C., so the 17 wt % value may be taken as an accurate assessment of the SWNT content in the crude soot, and is indicative of the SWNTs' stability. This value was found to be in good agreement with the yield determined by batch oxidation at 550° C. of SWNT material that is refluxed for 16 hr in 3 M HNO₃. In addition, as the data sets are virtually identical at the higher temperatures, despite the difference in the material weights which were lost during reflux, neither reflux consumes a significant quantity of the SWNT structures.

Although SWNT material that is refluxed for shorter times (e.g., 4 hours) may not oxidize as readily as SWNT material that is oxidized longer (e.g., 16 hours), extended reflux periods may damage the SWNT structures. That is, the TGA data for the SWNT material refluxed for only 4 hours was similar to that observed for the crude SWNT material. However, the TGA data 40 for the SWNT material refluxed for 48 hours indicated that some fraction of the SWNTs in the sample had been digested by the reflux process. In addition, the affinity for water following the extended reflux procedure is considerably less than that of the SWNT material that is refluxed for 16 hours, indicating that the easily-oxidized coating is not present.

The thick, uniform, hydrophilic carbon coating produced after a 16 hour reflux is not observed in TEM images. Instead, a generally thinner and patchy film was observed along with occasional agglomerations. The TEM images also indicated that the SWNT structures were sharply angled, cut, and damaged. These cut and defective SWNT structures may be more susceptible to oxidation such that only about 8 wt %, or less than 50% of the tubes known to be present, are found at the inflection point in the TGA data set 40 at 625° C., as shown in FIG. 6.

Although refluxing the crude SWNT material for 16 hours generally produced better results than a 4 hour reflux and a 48 hour reflux, the teachings of the invention are not to be limited to a 16 hour reflux. In other embodiments, the reflux time may be longer or shorter than 16 hours and may depend on design considerations.

Raman spectroscopy may also be used to ascertain certain properties of the highly purified SWNT product produced according to the method of the invention. Raman spectroscopy is an established analytical technique that provides highly accurate and definitive results. For example, Raman spectroscopy methods may be used to determine the tangential carbon displacement modes at various steps during the purification process, as shown in FIG. 7.

The Raman spectra shown in FIG. 7 for the crude SWNT material 50, 51 and for the purified SWNT material 60,61 both may exhibit a strong feature at about 1593 cm⁻¹ with shoulders (52, 62) at about 1567 and about 1609 cm⁻¹, respectively, as expected for the SWNT tangential carbon-atom displacement modes. However, the broadened feature at about 1349 cm⁻¹ in the crude SWNT spectrum 50, 51 (see inset in FIG. 7) indicates the presence of impurities and a contribution from the disordered sp2 carbon “D-band” of non-nanotube graphitic components. Following reflux, the D-band intensity significantly increases (spectrum 55, 56), indicating a decreasing domain size which may enhance purification of the SWNT material during oxidation. In addition, a signal derived from the fundamental E2g mode of disordered graphite may be observed where the SWNT modes are expected, and is indicative of the carbon coating formed on the SWNT structures during reflux. Charge transfer from intercalated nitric acid quenches the intensity of the SWNT E_{2g} mode. The D-band is narrower for the purified SWNT material (spectrum 60, 61).

Although the SWNT material has been characterized as described herein with respect to specific analysis techniques, it should be understood that the scope of the invention is not to be limited to any particular analysis technique for characterizing the SWNT material. Other microscopy processes and/or analysis techniques, now known or that may be later developed, that are suitable for characterizing the SWNT material during production and purification thereof according to embodiments of the invention, are also contemplated as being within the scope of the invention.

### EXAMPLES

In the first example, SWNT soot (i.e., crude SWNT material) was synthesized from pressed-graphite target material using a well-known pulsed laser vaporization technique, such as that which is described in more detail by A. Thess, et al., in Science 1996,273. More specifically, the technique employed for this example included the use of a single Nd:YAG laser in a free-running mode at an average power of about 4 to 6 Watts (W), and having an emission wavelength of 1064 nm. An optional gating rate of 10 Hertz (Hz) was used. The laser produced gated-laser light ranging in duration from 300 to 500 ns, and contained numerous short laser pulses ranging in duration from 5 to 15 ns.

The target material was made by pressing powered-graphite doped with 0.6 at % each of cobalt (Co) and nickel (Ni) in a 1⅛ inch dye. An argon flow of 100 sccm at 500 torr was maintained through the reaction vessel during the synthesis. The synthesis was retained in a vaporization regime by controlling the power density (Watts/cm²) to reduce or eliminate the formation of large graphite particles and/or graphite-encapsulated metal. The crude SWNT material (FIG. 1) was produced at about 1200° C., and the raw material contained about 20 to 30 wt % SWNT structures, based on a detailed analysis of TEM images. See A. C. Dillon, et al., Mater. Res. Soc. Conf Proc. 1998, 526, 403. ICPS indicated that the laser-generated crude material had the same metal content as the targets (about 6 wt %).

Approximately 80 mg of the crude SWNT material was refluxed in 60 mL of 3 molar (M) nitric acid for 16 hours at 120° C. Following reflux, the solid SWNT material was collected with a 1.5 inch diameter, 0.2 μm polypropylene filter coated with PTFE that allowed ready separation of the nanotubes from the nitric acid solution, and rinsed with deionized water. After drying, an 82 wt % yield was obtained. The weight lost is consistent with the digestion of the metal and about 12 wt % of the crude material. The reflux caused the non-nanotube carbon fractions to be redistributed as a uniform coating on the SWNTs, as shown in FIG. 2, and a paper-like material was obtained.

The refluxed SWNT material was oxidized in stagnant air inside a tube furnace at 550° C. for 30 minutes. As such, the carbon coating that was formed on the SWNT material during reflux was completely removed, leaving behind the highly purified SWNT product that is shown in FIG. 3. The oxidized SWNT material was also subjected to a high-temperature annealing process to any metal that was not removed during the reflux procedure and to establish order in the SWNT bundles. The purified SWNT product was heated to 1500° C. in a vacuum for ten minutes, and is shown after annealing in the TEM image of FIG. 4.

In another example, the procedure described for the first example was modified by using ashless filter paper to separate and collect the refluxed SWNT material. During oxidation, the filter material burned off (e.g., at less than 550° C.), and separated from the SWNT material collected thereon, during the ensuing oxidation process.

According to another example, the procedure described for the first example was modified by adding the following steps. Several samples (i.e., two in this example, although the invention is not limited to two samples) of refluxed SWNT material were collected on filters, as previously described, and suspended in 100 mL of toluene. The suspended material was evaporated with a Rotovap for several hours until the solution evaporated, at which time, a thin film of SWNT material was collected for oxidation, as described in the previous example. The process produced about twice the amount of highly purified SWNT product when two samples were used, illustrating one embodiment for scaling the method of the invention.

According to yet another example, the procedure described for the first example was modified by using a four inch filter in place of the 1.5 inch diameter filter for separating the SWNT material from the reflux solution (i.e., the HNO₃solution). The modifications to the procedure resulted in more than double the purified SWNT product. Again, this example illustrates another embodiment for scaling the method of the invention.

Although several embodiments have been disclosed for scaling the process of the present invention, it is understood that yet other embodiments are also contemplated as being within the scope of the invention. These examples are provided as illustrative of several preferred embodiments for scaling the process of the present invention.

Thermal gravimetric analysis (TGA) was used to evaluate the SWNT material during and after the purification process, as shown in FIG. 5. The TGA data indicated that the reflux process removed most, if not all of the metals. In addition, the TEM data indicated that the non-nanotube carbon fraction was arranged as a carbon coating on the SWNT structures during reflux. Also the TGA data indicated that the refluxed SWNT material is hygroscopic, making it more reactive toward oxidation.

Following oxidation, the TGA data indicated that most, if not all, of the non-nanotube carbon fraction was removed during oxidation. The sample was essentially highly purified SWNT product comprising about 26 wt % of the dry refluxed material, or about 21 wt % of the pre-reflux weight. This latter value is in excellent agreement with the yield measured after the refluxed material was heated to 550° C. in stagnant air (about 20 wt %), and considerably higher than the tube content determined by TGA analysis of the crude material (about 4 wt %). The quantitative agreement between the bulk oxidation in stagnant air and the TGA measurements under dynamic conditions indicates that neither route consumed an appreciable amount of the SWNT structures. In fact, neither longer times in stagnant air at 550° C. (up to 1 hour) nor holding at 550° C. during TGA produced further significant weight loss.

TGA was also used to evaluate the purity of the SWNT product. The decomposition temperature was determined by taking the derivative of the TGA curve shown in FIG. 5, and was 735° C. The final purity was estimated to be greater than 98 wt %, as less than 1 wt % was combusted below 550° C., and less than 1 wt % remained after heating to 850° C. The metal content of the highly purified SWNT product was measured to be less than 0.5 wt % by ICPS.

Raman spectroscopy was also used to ascertain various properties of the purified SWNT product. The Raman spectra shown in FIG. 7 for the crude SWNT material 50 and for the purified SWNT material 60 both exhibit a strong feature at about 1593 cm⁻¹ with shoulders (52, 62) at about 1567 and about 1609 cm⁻¹, respectively, as expected for the SWNT tangential carbon-atom displacement modes. The broadened feature at about 1349 cm⁻¹ in the crude SWNT spectrum 50, 51 indicates the presence of impurities and a contribution from the disordered sp2carbon “D band” of non-nanotube graphitic components. Following a 16 hour reflux, the D band intensity is significantly increased (spectrum 55, 56), indicating a decreasing domain size. In addition, a signal derived from the fundamental E2g mode of disordered graphite is observed where the SWNT modes are expected. The disordered graphite coating (see TEM image in FIG. 2) may prohibit observation of the resonantly enhanced SWNT modes. Charge transfer from intercalated nitric acid quenches the intensity of the SWNT E_{2g} mode. The D-band is narrower for the purified SWNT material (spectrum 60, 61).

It is readily apparent that the SWNT product produced according to embodiments of the method of the invention is highly purified. In addition, the purification process disclosed herein is non-destructive, and readily scalable. Consequently, the claimed invention represents an important development in SWNT purification techniques.

Having herein set forth preferred embodiments of the present invention, it is anticipated that suitable modifications can be made thereto which will nonetheless remain within the scope of the present invention. Therefore, it is intended that the appended claims be construed to include alternative embodiments of the invention except insofar as limited by the prior art.

What is claimed is:

1. A method for producing a highly purified single-wall carbon nanotube (SWNT) material, comprising:
refluxing a crude SWNT material in a solution to form a refluxed SWNT material having at least a partial carbon coating thereon; and
oxidizing said refluxed SWNT material to remove at least a portion of said carbon coating formed thereon.

2. The method of claim 1, further comprising removing at least a portion of metal incorporated in said crude SWNT material.

3. The method of claim 1, wherein said refluxing of said crude SWNT material is conducted in a dilute nitric acid solution.

4. The method of claim 1, further comprising separating said refluxed SWNT material from said solution before oxidizing said refluxed SWNT material.

5. The method of claim 4, wherein separating comprises filtering said refluxed SWNT material to produce a filtered SWNT material.

6. The method of claim 5, further comprising suspending said filtered SWNT material in another solution and evaporating said another solution to form a thin film of said refluxed SWNT material.

7. The method of claim 1, further comprising synthesizing said crude SWNT material.

8. The method of claim 7, wherein synthesizing said crude SWNT material is by long-laser pulsing of a graphite target.

9. The method of claim 8, further comprising maintaining the laser in a vaporization regime during synthesis.

10. The method of claim 7, further comprising reducing the occurrence of graphite and graphite-encapsulated particles during synthesis of said crude SWNT material.

11. A highly purified single-wall carbon nanotube (SWNT) produced according to the method of claim 1.

12. The highly purified single-wall carbon nanotube (SWNT) of claim 11, comprising less than about b 0.5 wt % of metal as determined by thermal gravimetric analysis (TGA).

13. The highly purified single-wall carbon nanotube (SWNT) of claim 11, characterized as at least 98 wt % pure SWNT material.

14. A non-destructive method for producing highly purified single-wall carbon nanotubes (SWNTs), comprising:
generating a crude SWNT material having at least a carbon nanotube fraction and a non-nanotube carbon fraction;
refluxing said crude SWNT material in an acid solution to produce a refluxed SWNT material, wherein at least a portion of said non-nanotube carbon fraction is redistributed as a uniform carbon coating on the carbon nanotube fraction; and
oxidizing said refluxed SWNT material to remove said uniform carbon coating formed thereon.

15. The method of claim 14, further comprising removing substantially all metal from said crude SWNT material during refluxing thereof.

16. The method of claim 14, further comprising forming a functional group on said uniform carbon coating to enhance removal of said uniform carbon coating.

17. The method of claim 14, further comprising decreasing the domain size of said non-nanotube carbon fraction to enhance removal of said uniform carbon coating.

18. The method of claim 14, further comprising annealing said oxidized SWNT material to remove substantially all metal remaining thereon.

19. The method of claim 14, wherein oxidizing said refluxed SWNT material is in a gas-phase oxidant.

20. The method of claim 14, wherein oxidizing said refluxed SWNT material is at about 550° C.

21. The method of claim 14, wherein oxidizing said refluxed SWNT material is for about 30 minutes.

22. The method of claim 14, further comprising drying said refluxed SWNT material.

23. The method of claim 14, further comprising separating said refluxed SWNT material from said acid solution.

24. The method of claim 14, wherein generating said crude SWNT material is by long-laser pulsing a graphite target.

25. The method of claim 24, further comprising operating a laser in free-running mode to produce gated laser light ranging in duration from 300 to 500 ns.

26. The method of claim 24, wherein said graphite target is made of pressed-powdered graphite having metal catalysts therein.

27. The method of claim 14, further comprising maintaining a laser in a vaporization regime during synthesis.

28. The method of claim 14, further comprising reducing the occurrence of graphite and graphite-encapsulated particles during synthesis of said crude SWNT material.

29. The method of claim 14, wherein refluxing is in 3M HNO₃ for 16 hours at 120° C.

30. The method of claim 14, wherein generating said crude SWNT material is by arc discharge.

31. The method of claim 14, wherein generating said crude SWNT material is by chemical vapor deposition.
